(19) United States
(12) Patent Application Publication
(10) Pub. No.: US 2016/0379802 A1
(43) Pub. Date: Dec. 29, 2016

(54) APPARATUS FOR MONITORING VACUUM ULTRAVIOLET AND PLASMA PROCESS EQUIPMENT INCLUDING THE SAME

(71) Applicant: SAMSUNG ELECTRONICS CO., LTD., SUWON-SI (KR)

(72) Inventors: Sejin OH, Hwaseong-si (KR); Dougyong SUNG, Seoul (KR); Kiho HWANG, Seoul (KR); Yun-Kwang JEON, Seoul (KR)

(21) Appl. No.: 15/161,432

(22) Filed: May 23, 2016

(30) Foreign Application Priority Data
Jun. 25, 2015 (KR) 10-2015-0090646

(51) Int. Cl. H01J 37/32; G01J 1/04; G01J 1/42; C23C 16/50; C23C 16/52

(52) U.S. Cl. CPC H01J 37/32082; C23C 16/50; C23C 16/52; G01J 1/429; G01J 1/0407; H01J 2237/334; H01J 2237/332

(57) ABSTRACT

An apparatus for monitoring vacuum ultraviolet, the apparatus including a light controller including a slit, the slit to transmit plasma emission light emitted from a process chamber in which a plasma process is performed on a substrate; a light selector adjacent to the light controller, the light selector selectively to transmit light, having a predetermined wavelength band, of the plasma emission light passing through the slit; a light collector to concentrate the light selectively transmitted by the light selector; and a detector to detect the light concentrated by the light collector, the light selectively transmitted by the light selector being vacuum ultraviolet.

### CROSS-REFERENCE TO RELATED APPLICATION

Korean Patent Application No. 10-2015-0090646, filed on Jun. 25, 2015, in the Korean Intellectual Property Office, and entitled: “Apparatus for Monitoring Vacuum Ultraviolet and Plasma Process Equipment Including the Same,” is incorporated by reference herein in its entirety.

### BACKGROUND

1. Field

Embodiments relate to an apparatus for monitoring vacuum ultraviolet.

2. Description of the Related Art

A plasma process may be necessary to manufacture a device including fine patterns, e.g., a semiconductor device. For example, the plasma may be used in a deposition process of a thin layer, an etching process, and an ashing process. Process distribution of the plasma may be accurately checked and exactly controlled to improve characteristics and yield of products.

### SUMMARY

Embodiments may be realized by providing an apparatus for monitoring vacuum ultraviolet, the apparatus including a light controller including a slit, the slit to transmit plasma emission light emitted from a process chamber in which a plasma process is performed on a substrate; a light selector adjacent to the light controller, the light selector selectively to transmit light, having a predetermined wavelength band, of the plasma emission light passing through the slit; a light collector to concentrate the light selectively transmitted by the light selector; and a detector to detect the light concentrated by the light collector, the light selectively transmitted by the light selector being vacuum ultraviolet.

The apparatus may further include a monitoring chamber having an inner space in a vacuum, the monitoring chamber having a connecting port connected to a first sidewall of the monitoring chamber. The connecting port may include a first connecting port and a second connecting port aligned with each other in a first direction, and the light controller may be between the first and second connecting ports.

The apparatus may further include a joint member having a window. The second connecting port may have a first end connected to the light controller and a second end opposite to the first end, and the joint member may be connected to the second end of the second connecting port.

The apparatus may further include a reference light source in the monitoring chamber, the reference light source to irradiate vacuum ultraviolet to the detector.

The reference light source may be a vacuum ultraviolet lamp.

The light selector may include a filter body rotatable on a rotation axis parallel to the first direction; and a plurality of light filters combined with the filter body. The light selector may be in the first connecting port.

The plurality of light filters may selectively and respectively transmit vacuum ultraviolet rays having different wavelength bands from each other.

The light collector may be a parabolic mirror.

The light collector and the detector may be spaced apart from each other in the monitoring chamber, and a distance between the light collector and the detector may be greater than 0 and equal to or less than 200 mm.

The light collector may be a convex lens.

The light collector may be in the first connecting port, the detector may be outside the monitoring chamber so as to be connected to a second sidewall of the monitoring chamber opposite to the first sidewall, and the light collector and the detector may be aligned with each other along the first direction.

The detector may be a photodiode or a photomultiplier tube.

Embodiments may be realized by providing plasma process equipment, including a process chamber having an inner space in which plasma is generated to treat a substrate, the process chamber having a window through which plasma emission light generated from the plasma is transmitted outward; and a vacuum ultraviolet-monitoring apparatus adjacent to the window, the vacuum ultraviolet-monitoring apparatus to selectively monitor vacuum ultraviolet, having a predetermined wavelength band, of the plasma emission light transmitted through the window, the vacuum ultraviolet-monitoring apparatus including a light controller including a slit to transmit the plasma emission light; a light selector adjacent to the light controller, the light selector to selectively transmit the vacuum ultraviolet, having the predetermined wavelength band, of the plasma emission light passing through the slit; a light collector to concentrate the vacuum ultraviolet selectively transmitted by the light selector; and a detector to detect the vacuum ultraviolet concentrated by the light collector.

The vacuum ultraviolet-monitoring apparatus may be attachable to and detachable from the process chamber.

The window may include a plurality of windows at different positions, and the vacuum ultraviolet-monitoring apparatus may include a plurality of vacuum ultraviolet-monitoring apparatuses corresponding to the positions of the plurality of windows, respectively.

Embodiments may be realized by providing an apparatus for monitoring vacuum ultraviolet, including a monitoring chamber having an inner process in a vacuum and having a connecting port connected to a first sidewall of the monitoring chamber, the connecting port including a first connecting port and a second connecting port aligned with each other in a first direction; a light controller between the first and second connecting ports, the light controller including a slit to transmit incident light; a light selector adjacent to the light controller in the first connecting port, the light selector to selectively transmit light, having a predetermined wavelength band, of the incident light passing through the slit; a light collector to concentrate the light selectively transmitted by the light selector; and a detector to detect the light concentrated by the light collector, the light selectively transmitted by the light selector being vacuum ultraviolet.

The apparatus may further include a joint member having a window. The second connecting port may have a first end connected to the light controller and a second end opposite to the first end, and the joint member may be connected to the second end of the second connecting port.

The apparatus may further include a vacuum ultraviolet lamp in the monitoring chamber, the vacuum ultraviolet lamp to irradiate vacuum ultraviolet to the detector.

The apparatus may further include a controller connected to the detector, the controller to control the detector, the light selector, and the vacuum ultraviolet lamp.

The light selector may include a filter body rotatable on a rotation axis parallel to the first direction and a plurality of light filters combined with the filter body, and the plurality of light filters may selectively and respectively transmit vacuum ultraviolet rays having different wavelength bands from each other.

### BRIEF DESCRIPTION OF THE DRAWINGS

Features will become apparent to those of skill in the art by describing in detail exemplary embodiments with reference to the attached drawings in which:

FIG. 1 illustrates a schematic cross-sectional view of plasma process equipment according to an embodiment;

FIG. 2 illustrates a schematic block diagram of an apparatus for monitoring vacuum ultraviolet according to an embodiment;

FIG. 3 illustrates a schematic plan view of an apparatus for monitoring vacuum ultraviolet according to an embodiment;

FIG. 4 illustrates a view of a light control unit of FIG. 3;

FIG. 5 illustrates a view of a light selector of FIG. 3;

FIG. 6 illustrates a schematic plan view of an apparatus for monitoring vacuum ultraviolet according to an embodiment;

FIG. 7 illustrates a schematic plan view of plasma process equipment according to an embodiment; and

FIG. 8 illustrates a schematic block diagram of a plasma process system according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

It will be understood that when an element such as a layer, region or substrate is referred to as being “on” another element, it can be directly on the other element or intervening elements may be present. In contrast, the term “directly” means that there are no intervening elements. In the drawings, the thicknesses of layers and regions may be exaggerated for clarity. The same reference numerals or the same reference designators denote the same elements throughout the specification.

Moreover, exemplary embodiments are described herein with reference to cross-sectional illustrations and/or plan illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. It will be also understood that although the terms first, second, third, etc., may be used herein to describe various elements, these elements should not be limited by these terms. These terms are only used to distinguish one element from another element. Thus, a first element in some embodiments could be termed a second element in other embodiments. Exemplary embodiments explained and illustrated herein include their complementary counterparts.

The terminology used herein is for the purpose of describing particular embodiments only and is not intended to be limiting. As used herein, the singular terms “a,” “an,” and “the” are intended to include the plural forms as well, unless the context clearly indicates otherwise. As used herein, the term “and/or” includes any and all combinations of one or more of the associated listed items. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Hereinafter, embodiments will be described in detail with reference to the accompanying drawings.

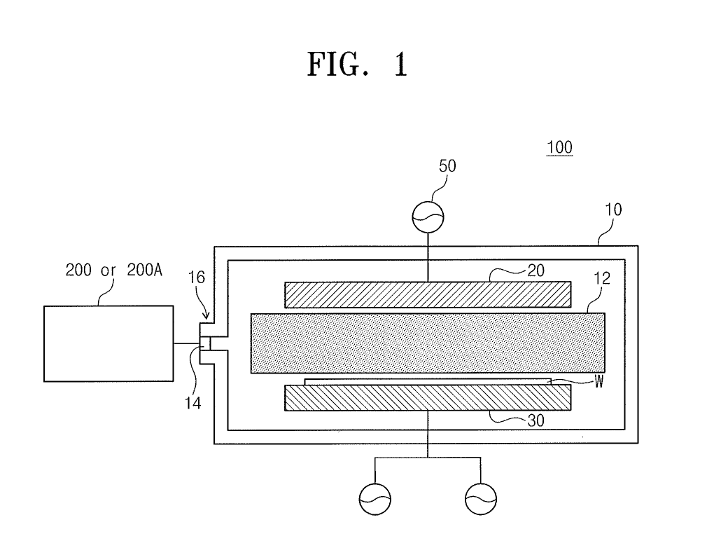

FIG. 1 illustrates a schematic cross-sectional view of plasma process equipment according to an embodiment. Plasma process equipment 100 may be capacitive coupled plasma (CCP) equipment, inductive coupled plasma (ICP) equipment, microwave plasma equipment, or another substrate-treating equipment using plasma. Referring to FIG. 1, the plasma process equipment 100 may include a process chamber 10, a top electrode 20, a bottom electrode 30, and an apparatus 200 or 200A for monitoring vacuum ultraviolet (hereinafter, referred to as a “vacuum ultraviolet-monitoring apparatus” 200 or 200A).

The process chamber 10 may include an inner space in which a process of a substrate W is performed. In the inner space, plasma 12 may be generated and the substrate W may be processed by the plasma 12. For example, the substrate W may be a semiconductor substrate used to manufacture a semiconductor device, or a glass substrate used to manufacture a flat display device. In an embodiment, the process of the substrate W may include, for example, an etching process, a chemical vapor deposition (CVD) process, an ashing process, and/or a cleaning process. In an embodiment, the process chamber 10 may have a sealed structure to maintain a vacuum. For example, the process chamber 10 may have a hollow hexahedral shape, a hollow cylindrical shape, or another shape. The plasma 12 may be induced in the process chamber 10 by high-frequency power 50 (e.g., a radio-frequency power) applied to the top and bottom electrodes 20 and 30. The high-frequency power 50 may be provided from a power supply to the top and bottom electrodes 20 and 30 through a matcher. The top electrode 20 and the bottom electrode 30 may be disposed over and under the substrate W, respectively. The top electrode 20 may include a showerhead that provides or sprays a plasma gas or an etching gas to the substrate W. The bottom electrode 30 may include a chuck fixing the substrate W.

A first window 14 may be provided to a first sidewall of the process chamber 10. The first window 14 may transmit infrared light, ultraviolet, or visible light. In particular, the first window 14 may transmit vacuum ultraviolet having a short wavelength of 200 nm or less. For example, the first window 14 may be formed of MgF₂ or CaF₂. In an embodiment, an opening 16 provided with the first window 14 may be sealed such that impurities do not flow into the process chamber 10 and the inner space of the process chamber 10 is maintained in a vacuum. In an embodiment, the opening 16 provided with the first window 14 may protrude from the process chamber 10. In an embodiment, the position of the first window 14 may be disposed in the sidewall of the process chamber 10. The first window 14 may be disposed at a top surface of the process chamber 10 or an exhaust portion of the process chamber 10. The first window 14 may be provided in plurality to the process chamber 10. The first window 14 may be anti-reflective coated. A transmittance of the first window 10 may be constant according to a wavelength of light. The plasma 12 may emit light having a proper wavelength according to a kind of the plasma gas or etching gas and a kind of an etch target layer reacting with the plasma gas or etching gas. The light emitted from the plasma 12 may be transmitted to the outside of the process chamber 10 through the first window 14.

The vacuum ultraviolet-monitoring apparatus 200 or 200A may be equipped to be adjacent to the first window 14 of the process chamber 10. In an embodiment, the vacuum ultraviolet-monitoring apparatus 200 or 200A may be connected to the first window 14 and may be fixed. According to an embodiment, the vacuum ultraviolet-monitoring apparatus 200 or 200A may be configured to be attachable to and detachable from the first window 14 of the process chamber 10. The vacuum ultraviolet-monitoring apparatus 200 or 200A may monitor the vacuum ultraviolet (i.e., extreme ultraviolet having a wavelength of 10 nm to 200 nm) of the light emitted from the plasma 12 and transmitted outward through the first window 14.

As sizes of patterns of semiconductor devices may be reduced, manufacturing processes using high-density plasma may be demanded. The high-density plasma may increase a density of high-energy electrons, and the amount of vacuum ultraviolet generated from plasma may be increased. The vacuum ultraviolet having high photon energy may penetrate into a semiconductor device during a plasma process, which may deteriorate reliability of the semiconductor device. For example, if a gate dielectric layer is formed using the plasma process, the vacuum ultraviolet emitted from plasma may penetrate into the gate dielectric layer to cause breakdown of the gate dielectric layer, variation of a threshold voltage may result, and reliability of a semiconductor device may be deteriorated. If a low-k dielectric layer is formed using the plasma process, vacuum ultraviolet emitted from plasma may dissociate chemical bonds of the low-k dielectric layer, a dielectric constant of the low-k dielectric layer may be increased, RC delay may increase to deteriorate reliability of a semiconductor device, and apparatuses capable of effectively monitoring vacuum ultraviolet and of being applied to mass-production equipment may be increasingly demanded to control the vacuum ultraviolet generated during the plasma process. The vacuum ultraviolet-monitoring apparatus 200 or 200A according to embodiments may satisfy such demands.

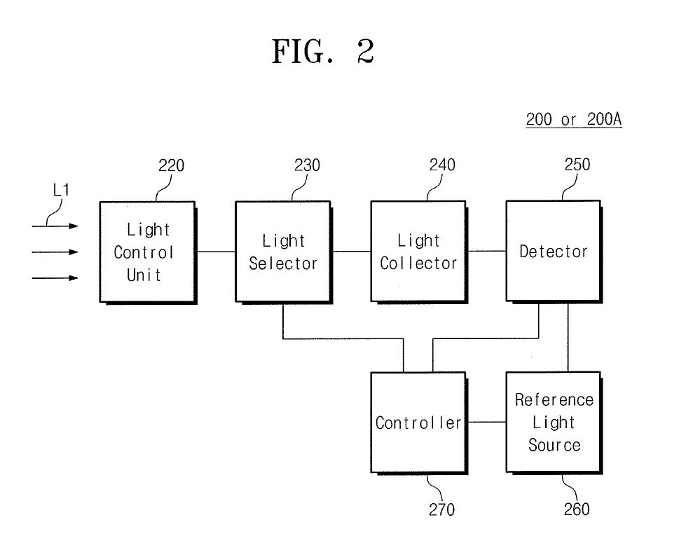

Hereinafter, the vacuum ultraviolet-monitoring apparatus 200 will be described in detail with reference to FIGS. 2 to 5.

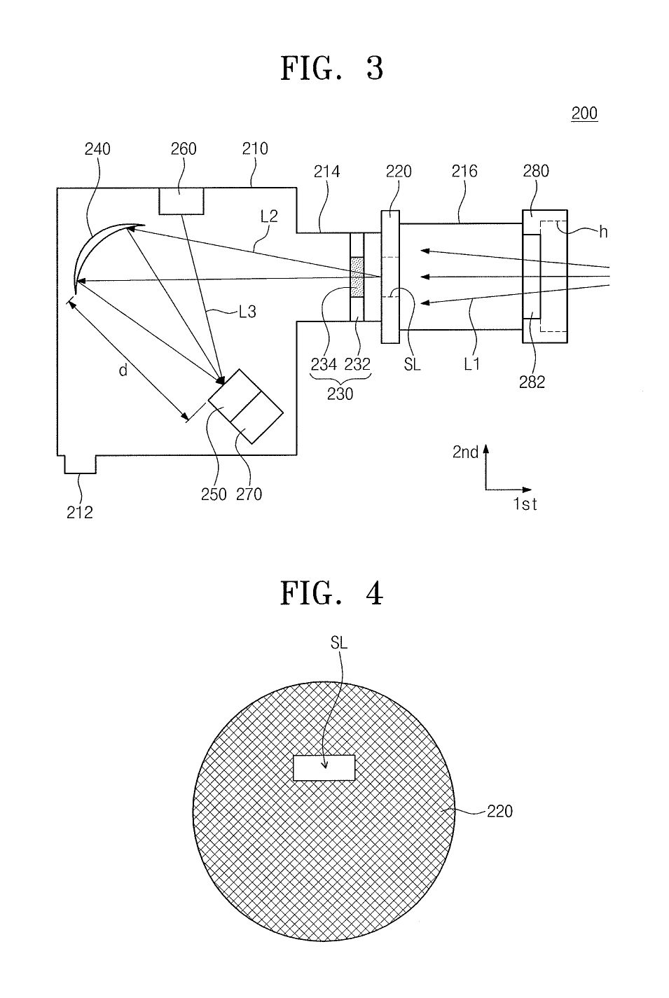

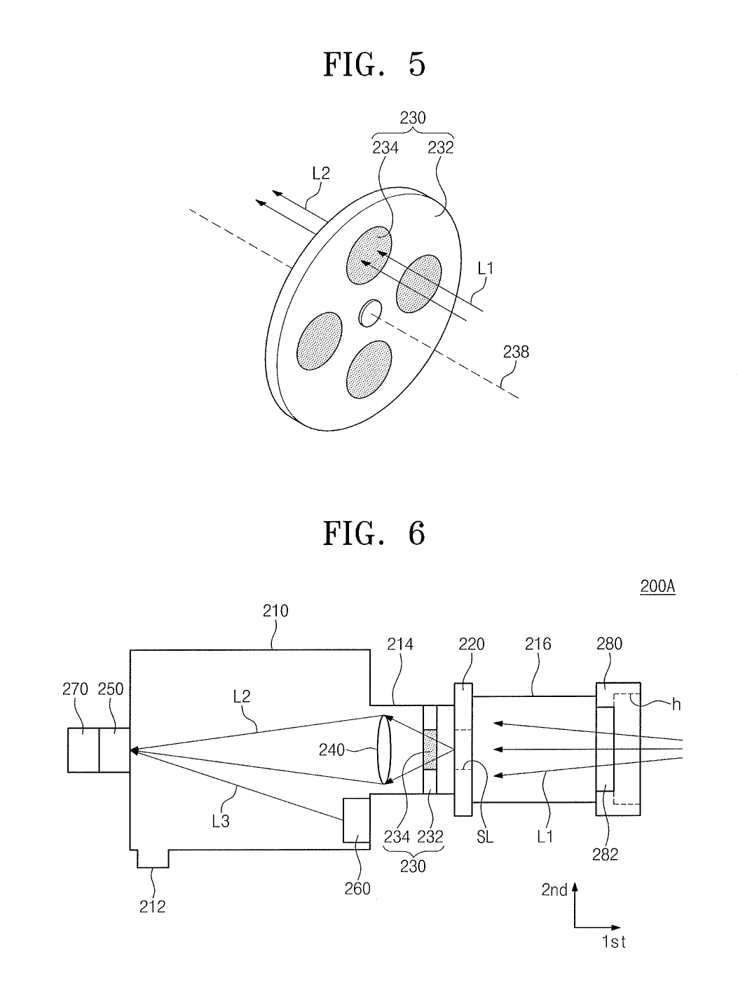

FIG. 2 illustrates a schematic block diagram of an apparatus for monitoring vacuum ultraviolet according to an embodiment. FIG. 3 illustrates a schematic plan view of an apparatus for monitoring vacuum ultraviolet according to an embodiment. FIG. 4 illustrates a view of a light control unit of FIG. 3. FIG. 5 illustrates a view of a light selector of FIG. 3.

Referring to FIGS. 2 to 5, the vacuum ultraviolet-monitoring apparatus 200 may include a monitoring chamber 210, a light control unit 220, a light selector 230, a light collector 240, a detector 250, a reference light source 260, and a controller 270.

The monitoring chamber 210 may have an inner space that is in a vacuum. The inner space of the monitoring chamber 210 may be maintained in a vacuum while monitoring the vacuum ultraviolet. The monitoring chamber 210 may have a plurality of ports. In an embodiment, the plurality of ports may include a pumping port 212 and a connecting port. When the vacuum of the monitoring chamber 210 is broken (e.g., an inner pressure of the monitoring chamber 210 increases to 300 mmTorr or more), a vacuum pump may be connected to the pumping port 212 to pump air in the inner space of the monitoring chamber 210. On the other hand, the vacuum pump may be separated from the vacuum ultraviolet-monitoring apparatus 200 during monitoring of the vacuum ultraviolet. The connecting port may include a first connecting port 214 and a second connecting port 216. A first end of the first connecting port 214 may be connected to a first sidewall of the monitoring chamber 210, and the second connecting port 216 may be aligned with the first connecting port 214 in a first direction. The first and second connecting ports 214 and 216 may induce light L1, transmitted from the process chamber 10, into the monitoring chamber 210. The light L1 may correspond to light emitted from plasma in the process chamber 10. Hereinafter, the light L1 emitted from the plasma is referred to as ‘plasma emission light L1’.

The light control unit 220 may be provided between the first connecting port 214 and the second connecting port 216. The light control unit 220 may be combined with a second end of the first connecting port 214 and a first end of the second connecting port 216. A joint member 280 may be provided to a second end of the second connecting port 216. The vacuum ultraviolet-monitoring apparatus 200 may be connected and fixed to the first window 14 of the plasma process equipment 100 by the joint member 280. In an embodiment, the joint member 280 may have a joint hole h, and the opening 16 of the plasma process equipment 100 may be inserted and fixed into the joint hole h of joint member 280.

In an embodiment, the shape of the joint member 280 may be variously modified as the need arises, and due to, for example, the joint member 280, the vacuum ultraviolet-monitoring apparatus 200 may have the structure which is attachable to and detachable from the first window 14 of the plasma process equipment 100. The joint member 280 may have a second window 282. The second window 282 may be formed of the same material as the first window 14 of the plasma process equipment 100. The second window 282 may be formed of MgF₂ or CaF₂. The plasma emission light L1 transmitted through the first window 14 may be incident on the inside of the vacuum ultraviolet-monitoring apparatus 200 through the second window 282.

The light control unit 220 may have a slit SL through which the plasma emission light L1 provided through the second window 282 passes. As illustrated in FIG. 4, the slit SL may have a rectangular shape. In an embodiment, the slit SL may have a circular shape or a plurality of pin-hole shapes. The light control unit 220 may adjust an incident range of the plasma emission light L1 transmitted through the second window 282 by means of the slit SL.

The light selector 230 may be provided in the first connecting port 214. The light selector 230 may be disposed adjacently to the light control unit 220. According to an embodiment, the light selector 230 may include a filter body 232 and a plurality of light filters 234 combined with the filter body 232. The filter body 232 may be formed of a metal or a light-shielding material, e.g., a material opaque to the vacuum ultraviolet to be monitored. The filter body 232 may have a circular plate shape, and the plurality of light filters 234 may be combined with the filter body 232 at regular intervals along a circumferential direction of the filter body 232. The light filters 234 may be attachable to and detachable from the filter body 232, and each of the light filters 234 may be replaced as needed for monitoring different wavelength bands.

In FIG. 5, four light filters 234 may be combined with the filter body 232. In an embodiment, the number of the light filters 234 may be smaller than four or may be greater than four. The plurality of light filters 234 may selectively transmit vacuum ultraviolet rays having different wavelength bands from each other. Central wavelengths of the vacuum ultraviolet rays respectively transmitted through the light filters 234 may be different from each other. The filter body 232 may be rotatable on a rotation axis parallel to the first direction in which the first connecting port 214, the light control unit 220, and the second connecting port 216 are aligned with each other.

In an embodiment, a driving member for rotating the filter body 232 may be coupled to the filter body 232. Each of the light filters 234 may be rotated by the rotation of the filter body 232 so as to be aligned with the slit SL of the light control unit 220. The incident range of the plasma emission light L1 may be adjusted by the slit SL, the plasma emission light L1 passing through the slit SL may be provided to the light filter 234 aligned with the slit SL, and the plasma emission light L1 may be filtered by the light filter 234 aligned with the slit SL.

The wavelength band of the vacuum ultraviolet emitted from the plasma 12 of FIG. 1 may be various according to the kind of the plasma process gas. The light selector 230 may be controlled to align the light filter 234 that matches the wavelength band of the vacuum ultraviolet desired to be monitored, with the slit SL. Thus, the vacuum ultraviolet having one of various wavelength bands may be selected without an additional monochromator. The controller 270 may control the light selector 230 to select a desired light filter 234. The controller 270 may rotate the filter body 232 to align the desired light filter 234 with the slit SL.

The vacuum ultraviolet-monitoring apparatus 200 according to embodiments may monitor the vacuum ultraviolet rays of various wavelength bands. The vacuum ultraviolet-monitoring apparatus 200 may be applied to various plasma processes by employing different light filters 234 as appropriate. Hereinafter, the vacuum ultraviolet of the plasma emission light L1, which is filtered by the light selector 230, is defined as a first vacuum ultraviolet L2.

The light collector 240 may be provided in the monitoring chamber 210. The light collector 240 may be disposed at an optical path of the first vacuum ultraviolet L2 provided into the monitoring chamber 210 so as to change the optical path of the first vacuum ultraviolet L2. The light collector 240 may concentrate the first vacuum ultraviolet L2 to the detector 250. In the present embodiment, the light collector 240 may be a parabolic mirror.

The detector 250 may be provided in the monitoring chamber 210 and may be spaced apart from the light collector 240. According to an embodiment, a distance d between the detector 250 and the light collector 240 may be 200 mm or less. Here, the distance d may be defined as the minimum distance between the detector 250 and the light collector 240. The vacuum ultraviolet-monitoring apparatus 200 according to embodiments may select one of vacuum ultraviolet rays having various wavelength bands and may measure the selected vacuum ultraviolet without an additional monochromator (e.g., a grating). Thus, the distance d between the light collector 240 and the detector 250 for increasing spatial resolution need not be increased, reducing a size of the vacuum ultraviolet-monitoring apparatus 200.

The vacuum ultraviolet-monitoring apparatus 200 may change a sensitivity of the detector 250 to adjust a ratio of a vacuum ultraviolet signal to noise and may adjust time resolution of the detector 250 to a millisecond or less to monitor the vacuum ultraviolet of the process chamber 10 in real time. The detector 250 may include, for example, a photodiode or a photomultiplier tube (PMT). The detector 250 may measure the first vacuum ultraviolet L2 concentrated thereto and may convert the first vacuum ultraviolet L2 into an electrical signal. The electrical signal of the first vacuum ultraviolet L2 converted by the detector 250 may be transmitted to the controller 270. The controller 270 may amplify the electrical signal transmitted from the detector 250 and may calculate the amplified signal to extract data with respect to a plasma characteristic (e.g., the amount of emission of the vacuum ultraviolet) of the process chamber 10. The extracted data may be stored in the controller 270 or may be transmitted to an external system.

The reference light source 260 may be provided in the monitoring chamber 210. The reference light source 260 may irradiate vacuum ultraviolet having a constant intensity to the detector 250. The reference light source 260 may be a vacuum ultraviolet (VUV) lamp. Hereinafter, the vacuum ultraviolet irradiated from the reference light source 260 is defined as a second vacuum ultraviolet L3. The reference light source 260 may be used as a member sensing a variation in pressure of the vacuum state of the monitoring chamber 210. The controller 270 may reflect the vacuum state of the monitoring chamber 210 obtained using the reference light source 260 to the measured value (e.g., the intensity) of the first vacuum ultraviolet L2 measured by the detector 250, thereby performing a calibration process of the measure value of the first vacuum ultraviolet L2.

In more detail, the vacuum state of the monitoring chamber 210 may be varied as time passes. Air may flow into the monitoring chamber 210 as time passes, the inner pressure of the monitoring chamber 210 may increase, the first vacuum ultraviolet L2 incident on the inside of the monitoring chamber 210 may be strongly absorbed by the air in the monitoring chamber 210, and the measured value of the first vacuum ultraviolet L2 measured by the detector 250 may be distorted. The calibration process performed by the controller 270 means that an absorption degree of the first vacuum ultraviolet L2 in the monitoring chamber 210 is reflected to correct the distortion of the measured value of the first vacuum ultraviolet L2. The reference light source 260 may provide reference data used to calculate the absorption degree of the first vacuum ultraviolet L2.

In detail, the second vacuum ultraviolet L3 having a constant wavelength band and a constant intensity may be irradiated to the detector 250 in the monitoring chamber 210 which in an initial vacuum state before the plasma process, and the detector 250 may measure the intensity of the second vacuum ultraviolet L3. The measured value of the second vacuum ultraviolet L3 in the initial vacuum state may correspond to a reference value of the reference light source 260 which is used to calculate an absorption degree of the second vacuum ultraviolet L3.

Thereafter, when the plasma process is performed, the same process as described above (i.e., irradiation and measurement of the second vacuum ultraviolet L3 having the same wavelength band and the same intensity) may be performed immediately before the generation of the plasma 12. The measured value of the second vacuum ultraviolet L3 obtained by this process may correspond to a comparison value of the reference light source 260 which is used to calculate the absorption degree of the second vacuum ultraviolet L3.

The controller 270 may compare the reference value with the comparison value to calculate the absorption degree of the second vacuum ultraviolet L3. The controller 270 may calculate the absorption degree of the first vacuum ultraviolet L2 based on the calculated absorption degree of the second vacuum ultraviolet L3, and the measured value of the first vacuum ultraviolet L2 obtained during the plasma process may be calibrated using the calculated absorption degree of the first vacuum ultraviolet L2. According to an embodiment, the above mentioned process of obtaining the comparison value may be performed each time when the plasma process is performed.

The controller 270 may control operations of the light selector 230, the detector 250, and the reference light source 260. In the present embodiment, the controller 270 may be combined with the detector 250, and the controller 270 and the detector 250 may be provided in the monitoring chamber 210. In an embodiment, the controller 270 may be separated from the detector 250 or may be provided outside the monitoring chamber 210. A power source unit may be provided in or outside the monitoring chamber 210 to provide powers for operating the light selector 230, the detector 250, the controller 270, and/or the reference light source 260.

FIG. 6 illustrates a schematic plan view of an apparatus for monitoring vacuum ultraviolet according to an embodiment. In the vacuum ultraviolet-monitoring apparatus 200A according to the present embodiment, the same elements as described in the embodiment of FIGS. 2 to 5 will be indicated by the same reference numerals or the same reference designators. For the purpose of ease and convenience in explanation, the descriptions to the same elements as in the embodiment of FIGS. 2 to 5 will be omitted or mentioned briefly. Differences between the present embodiment and the above embodiment will be mainly described.

Referring to FIG. 6, a light collector 240, e.g., an element having optical power, may be provided in the first connecting port 214. The light collector 240 may be disposed at the optical path of the first vacuum ultraviolet L2 transmitted through the light selector 230. The light collector 240 may concentrate the first vacuum ultraviolet L2 to the detector 250. In the present embodiment, the light collector 240 may be a convex lens.

The detector 250 may be provided outside of the monitoring chamber 210. The monitoring chamber 210 may have a first sidewall connected to the first connecting port 214 and a second sidewall opposite to the first sidewall, and the detector 250 may be connected to the second sidewall. The light control unit 220, the light selector 230, the light collector 240, and the detector 250 may be aligned with each other along a first direction.

The reference light source 260 may be provided in the monitoring chamber 210. The reference light source 260, for example, may be adjacent to the first sidewall of the monitoring chamber 210 which is connected to the first connecting port 214. In an embodiment, the reference light source 260 may irradiate the second vacuum ultraviolet L3 to the detector 250. The controller 270 may be combined with the detector 250 and may be provided outside the monitoring chamber 210. Other elements of the vacuum ultraviolet-monitoring apparatus 200A may be substantially the same as corresponding elements of the vacuum ultraviolet-monitoring apparatus 200 of FIGS. 2 to 5.

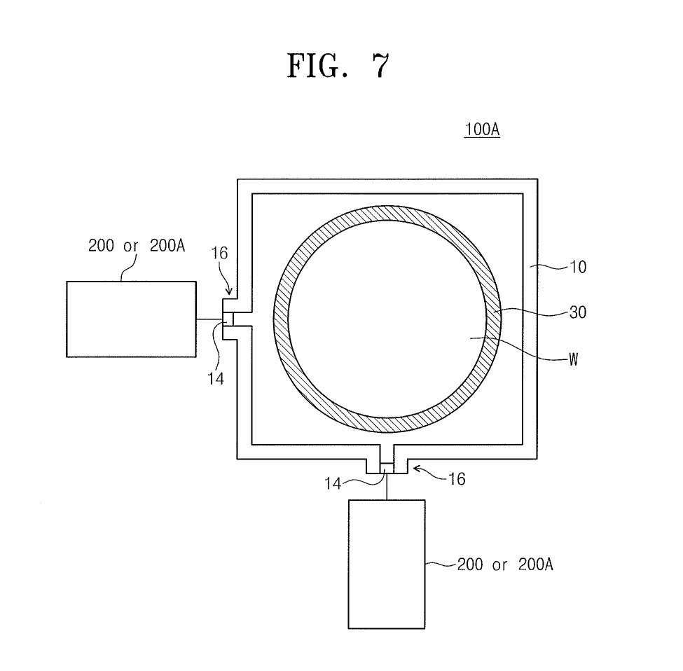

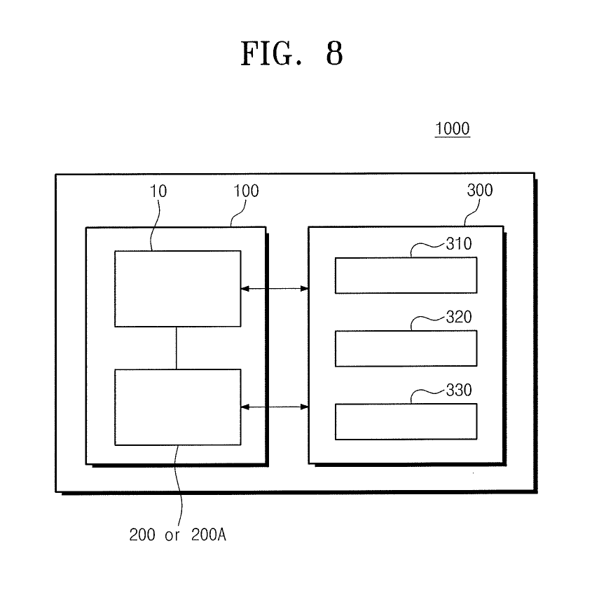

FIG. 7 illustrates a schematic plan view of plasma process equipment according to an embodiment. Plasma process equipment 100A of FIG. 7 may have the substantially same or similar shape and function as the plasma process equipment 100 of FIG. 1. In an embodiment, the plasma process equipment 100A of FIG. 7 may include a plurality of vacuum ultraviolet-monitoring apparatuses 200 and/or 200A. The plurality of vacuum ultraviolet-monitoring apparatuses 200 and/or 200A may be provided at different positions of the plasma process equipment 100A. In an embodiment, the plurality of vacuum ultraviolet-monitoring apparatuses 200 and/or 200A may be located to corresponding to first windows 14 disposed at different positions of the process chamber 10, and the plurality of vacuum ultraviolet-monitoring apparatuses 200 and/or 200A may monitor the vacuum ultraviolet with respect to a wider space in the process chamber 10.

Hereinafter, a plasma process system controlling the plasma process equipment will be described with reference to FIG. 8. FIG. 8 illustrates a schematic block diagram of a plasma process system according to an embodiment.

Referring to FIG. 8, a plasma process system 1000 may include plasma process equipment 100 including at least one process chamber 10 and a vacuum ultraviolet-monitoring apparatus 200 or 200A connected to the process chamber 10, and a system controller 300 controlling the plasma process equipment 100.

The process chamber 10 may generate plasma, and the vacuum ultraviolet-monitoring apparatus 200 or 200A may measure vacuum ultraviolet of the plasma generated in the process chamber 10. Results measured by the vacuum ultraviolet-monitoring apparatus 200 or 200A may be converted into electrical signals or digital data, and the electrical signals or digital data may be transmitted to the system controller 300. The system controller 300 may control the plasma process equipment 100 such that desired plasma characteristics (e.g., the amount of emission of the vacuum ultraviolet) may be realized on the basis of analysis of the measured results.

The system controller 300 may include a communication unit 310, a processing unit 320, and a storage unit 330. The communication unit 310 may receive the measured data from the vacuum ultraviolet-monitoring apparatus 200 or 200A, and the processing unit 320 may calculate plasma characteristic data (e.g., the amount of the vacuum ultraviolet of the plasma generated in the process chamber 10) from the measured data. The storage unit 330 may store an algorithm for the receipt and calculation, the measured data, and the plasma characteristic data. The system controller 300 may control at least one of the process gas or the high-frequency power provided into the process chamber 10 on the basis of the plasma characteristic data. The plasma characteristic data may be used to control process characteristics of the plasma process equipment 100. The plasma process system 1000 described above may also be applied to the plasma process equipment 100A of FIG. 7.

By way of summation and review, a monochromator of analyzing plasma emission light based on a wavelength of light may measure light in a visible wavelength band ranging from 300 nm to 900 nm. As sizes of patterns formed using plasma may be reduced, the plasma process may use high-density plasma. The monochromator may not measure vacuum ultraviolet that has a wavelength of 300 nm or less and is generated from high-density plasma.

Techniques such as optical emission spectroscopy (OES) and voltage-current probe may measure and check characteristics of plasma. Such techniques may not measure vacuum ultraviolet of 200 nm or less, which is generated and emitted by high-density plasma.

Apparatuses for measuring the vacuum ultraviolet (e.g., a vacuum ultraviolet (VUV) detector or a VUV sensor) may measure light having a wide wavelength band (e.g., a wavelength band from 100 nm to 200 nm) without resolution with respect to a wavelength of the vacuum ultraviolet, and the apparatuses for measuring the vacuum ultraviolet may check a total intensity of the whole vacuum ultraviolet emitted from the plasma, and may not check the wavelength of vacuum ultraviolet emitted from a specific plasma process.

Detection of vacuum ultraviolet having a specific wavelength by spectral resolution may be performed by a vacuum ultraviolet monochromator. The vacuum ultraviolet monochromator may need a high-priced spectral resolution apparatus (e.g., a grating) and a complex apparatus (e.g., charge coupled device (CCD) or a photomultiplier tube (PMT)). A vacuum apparatus which may be heavy and expensive may be connected to the vacuum ultraviolet monochromator, a size of the whole system may be increased, and it may be difficult to move the whole system.

An optical system separating the vacuum ultraviolet by the grating may be used, and a motor driving unit may be required to rotate the grating. Alignment may be an important factor due to, for example, the optical system, and misalignment may occur when the vacuum ultraviolet monochromator is moved in a manufacturing line. The vacuum ultraviolet monochromator may need a process of calibrating a wavelength of light through a relative equation between the grating and the motor driving unit. Misalignment may occur by the movement, and a calibration process using reference light may be performed again. If a focus distance of a wavelength of light resolved after passing through the grating is 20 cm in the vacuum ultraviolet monochromator using the grating, a measurement range variation of 300 μM may occur for resolution of 10 nm, and a high-priced motor controller for finely adjusting the grating may be demanded. When the performance of the grating is improved to increase spatial resolution, cost may increase. When the focus distance is increased to 50 cm or more to increase the spatial resolution, a size of a system including vacuum ultraviolet monochromator may be increased, and it may be difficult to move the system.

In contrast, the vacuum ultraviolet-monitoring apparatus according to embodiments may have a small size and may be easily attachable to and detachable from plasma process equipment. The vacuum ultraviolet-monitoring apparatus according to embodiments may be applied to various plasma processes, the vacuum ultraviolet-monitoring apparatus may be easily installed on mass-production equipment, and the vacuum ultraviolet generated during the plasma process may be effectively monitored to prevent deterioration of reliability of the semiconductor device manufactured using the plasma process.

The vacuum ultraviolet-monitoring apparatus according to embodiments may have a small size and may be attachable to and detachable from plasma process equipment. The vacuum ultraviolet-monitoring apparatus may be applied to various plasma processes, the vacuum ultraviolet-monitoring apparatus may be easily installed on mass-production equipment used to manufacture semiconductor devices, and the vacuum ultraviolet generates during the plasma process may be effectively monitored to prevent deterioration of the reliability of semiconductor devices manufactured using the plasma process.

Embodiments relate to an apparatus for monitoring vacuum ultraviolet generated during a plasma process and plasma process equipment including the same. Embodiments may provide an apparatus for monitoring vacuum ultraviolet which may be capable of being easily installed in mass-production equipment and of being applied to various plasma processes.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An apparatus for monitoring vacuum ultraviolet, the apparatus comprising:
a light controller including a slit, the slit to transmit plasma emission light emitted from a process chamber in which a plasma process is performed on a substrate;
a light selector adjacent to the light controller, the light selector selectively to transmit light, having a predetermined wavelength band, of the plasma emission light passing through the slit;
a light collector to concentrate the light selectively transmitted by the light selector; and
a detector to detect the light concentrated by the light collector,
the light selectively transmitted by the light selector being vacuum ultraviolet.

2. The apparatus as claimed in claim 1, further comprising a monitoring chamber having an inner space in a vacuum, the monitoring chamber having a connecting port connected to a first sidewall of the monitoring chamber,
wherein the connecting port includes a first connecting port and a second connecting port aligned with each other in a first direction, and
wherein the light controller is between the first and second connecting ports.

3. The apparatus as claimed in claim 2, further comprising a joint member having a window,
wherein the second connecting port has a first end connected to the light controller and a second end opposite to the first end, and
wherein the joint member is connected to the second end of the second connecting port.

4. The apparatus as claimed in claim 2, further comprising a reference light source in the monitoring chamber, the reference light source to irradiate vacuum ultraviolet to the detector.

5. The apparatus as claimed in claim 4, wherein the reference light source is a vacuum ultraviolet lamp.

6. The apparatus as claimed in claim 2, wherein the light selector includes:
a filter body rotatable on a rotation axis parallel to the first direction; and
a plurality of light filters combined with the filter body,
wherein the light selector is in the first connecting port.

7. The apparatus as claimed in claim 6, wherein the plurality of light filters selectively and respectively transmit vacuum ultraviolet rays having different wavelength bands from each other.

8. The apparatus as claimed in claim 2, wherein the light collector is a parabolic mirror.

9. The apparatus as claimed in claim 8, wherein:
the light collector and the detector are spaced apart from each other in the monitoring chamber, and
a distance between the light collector and the detector is greater than 0 and equal to or less than 200 mm.

10. The apparatus as claimed in claim 2, wherein the light collector is a convex lens.

11. The apparatus as claimed in claim 10, wherein:
the light collector is in the first connecting port,
the detector is outside the monitoring chamber so as to be connected to a second sidewall of the monitoring chamber opposite to the first sidewall, and
the light collector and the detector are aligned with each other along the first direction.

12. The apparatus as claimed in claim 2, wherein the detector is a photodiode or a photomultiplier tube.

13. Plasma process equipment, comprising:
a process chamber having an inner space in which plasma is generated to treat a substrate, the process chamber having a window through which plasma emission light generated from the plasma is transmitted outward; and
a vacuum ultraviolet-monitoring apparatus adjacent to the window, the vacuum ultraviolet-monitoring apparatus to selectively monitor vacuum ultraviolet, having a predetermined wavelength band, of the plasma emission light transmitted through the window,
the vacuum ultraviolet-monitoring apparatus including:
a light controller including a slit to transmit the plasma emission light;
a light selector adjacent to the light controller, the light selector to selectively transmit the vacuum ultraviolet, having the predetermined wavelength band, of the plasma emission light passing through the slit;
a light collector to concentrate the vacuum ultraviolet selectively transmitted by the light selector; and
a detector to detect the vacuum ultraviolet concentrated by the light collector.

14. The plasma process equipment as claimed in claim 13, wherein the vacuum ultraviolet-monitoring apparatus is attachable to and detachable from the process chamber.

15. The plasma process equipment as claimed in claim 13, wherein:
the window includes a plurality of windows at different positions, and
the vacuum ultraviolet-monitoring apparatus includes a plurality of vacuum ultraviolet-monitoring apparatuses corresponding to the positions of the plurality of windows, respectively.

16. An apparatus for monitoring vacuum ultraviolet, comprising:
a monitoring chamber having an inner process in a vacuum and having a connecting port connected to a first sidewall of the monitoring chamber, the connecting port including a first connecting port and a second connecting port aligned with each other in a first direction;
a light controller between the first and second connecting ports, the light controller including a slit to transmit incident light;
a light selector adjacent to the light controller in the first connecting port, the light selector to selectively transmit light, having a predetermined wavelength band, of the incident light passing through the slit;
a light collector to concentrate the light selectively transmitted by the light selector; and
a detector to detect the light concentrated by the light collector,
the light selectively transmitted by the light selector being vacuum ultraviolet.

17. The apparatus as claimed in claim 16, further comprising a joint member having a window,
wherein the second connecting port has a first end connected to the light controller and a second end opposite to the first end, and
wherein the joint member is connected to the second end of the second connecting port.

18. The apparatus as claimed in claim 16, further comprising a vacuum ultraviolet lamp in the monitoring chamber, the vacuum ultraviolet lamp to irradiate vacuum ultraviolet to the detector.

19. The apparatus as claimed in claim 18, further comprising a controller connected to the detector, the controller to control the detector, the light selector, and the vacuum ultraviolet lamp.

20. The apparatus as claimed in claim 16, wherein:
the light selector includes a filter body rotatable on a rotation axis parallel to the first direction and a plurality of light filters combined with the filter body, and
the plurality of light filters selectively and respectively transmit vacuum ultraviolet rays having different wavelength bands from each other.
